(19) United States
(12) Patent Application Publication
(10) Pub. No.: US 2026/0218030 A1
(43) Pub. Date: Jul. 30, 2026

(54) NON-CURABLE THERMAL GREASE WITH BORON NITRIDE

(71) Applicants: Dow Silicones Corporation, Midland, MI (US); Dow Global Technologies LLC, Midland, MI (US)

(72) Inventors: Zhanjie LI, Midland, MI (US); Dorab Bhagwagar, Saginaw, MI (US); Ryan Maar, Midland, MI (US); Danielle Berry, Bay City, MI (US); Peng Wei, Shanghai (CN)

(21) Appl. No.: 19/142,383

(22) PCT Filed: Jan. 13, 2023
(86) PCT No.: PCT/CN2023/072051

§ 371 Date: Jun. 23, 2025

(51) Int. Cl. C09K 5/14; C08G 77/38; C08K 3/08; C08K 3/22; C08K 7/00; H05K 7/20

(52) U.S. Cl. CPC C09K 5/14; C08G 77/38; C08K 3/08; C08K 3/22; C08K 7/00; H05K 7/2039; C08K 2003/0812; C08K 2003/2296; C08K 2201/001

(57) ABSTRACT

The present invention relates to a non-curable thermal grease comprising filler particles, boron nitride platelet particles, and a trialkoxysilyl-terminated polydimethylsiloxane. The non-curable thermal grease is useful as a thermal interface material in microelectronic devices to transport heat generated by a heat source to a heat sink.

### BACKGROUND OF THE INVENTION

The present invention relates to a composition comprising a non-curable thermal grease containing boron nitride. Non-curable thermal greases are useful as a thermal interface material in microelectronic devices to transport heat generated by a heat source to a heat sink.

Non-curable thermal greases contain large amounts of one or more thermally conductive fillers such as zinc oxide, alumina (i.e., Al₂O₃), and aluminum dispersed in a non-curable polyorganosiloxane matrix. They have high thermal conductivity, low thermal resistance, and low disassembly force. For applications with bare die chip architecture where a thermal grease is applied directly as a thermal interface material between the die and the heat sink, die warpage during power cycling leads to repeated movement of the die, which tends to squeeze thermal grease out of the interface. This loss of thermal grease—also known as pump-out—leads to the formation of hotspots on the die, which damage its performance. It would therefore be desirable to prepare a non-curable thermal grease with improved pump-out resistance, while maintaining acceptable printability and thermal conductivity.

### SUMMARY OF THE INVENTION

The present invention addresses a need in the art by providing a non-curable thermal grease composition comprising, based on the weight of the composition, a) from 80 to 95 weight percent of one or more filler particles selected from the group consisting of aluminum, alumina, and zinc oxide; b) from 0.2 to 8 weight percent boron nitride platelet particles; and c) 0.2 to 10 weight percent of a trialkoxylated polydimethylsiloxane of structure 1:

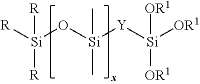

where R and R¹ are each independently C₁-C₆-alkyl, Y is O or CH₂—CH₂; and x is from 30 to 200; wherein the non-curable thermal grease composition comprises d) up to 10 weight percent of a polydimethylsiloxane or poly (phenylmethylsiloxane-co-dimethylsiloxane) carrier fluid having a viscosity in the range of from 30 cSt to 200 cSt. The non-curable thermal grease of the present invention provides excellent pump-out resistance, while retaining acceptable printability, thermal conductivity, and viscosity.

### DETAILED DESCRIPTION OF THE INVENTION

The present invention is a non-curable thermal grease composition comprising, based on the weight of the composition, a) from 80 to 95 weight percent of one or more filler particles selected from the group consisting of aluminum, alumina, and zinc oxide; b) from 0.2 to 8 weight percent boron nitride platelet particles; and c) 0.2 to 10 weight percent of a trialkoxylated polydimethylsiloxane of structure 1:

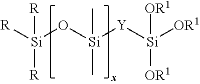

where R and R¹ are each independently C₁-C₆-alkyl, Y is O or CH₂—CH₂; and x is from 30 to 200; wherein the non-curable thermal grease composition comprises d) up to 10 weight percent of a polydimethylsiloxane or poly (phenylmethylsiloxane-co-dimethylsiloxane) carrier fluid having a viscosity in the range of from 30 cSt to 200 cSt.

The composition preferably comprises aluminum and zinc oxide and/or alumina filler particles at a concentration in the range of from 85 or from 90 weight percent to 95 weight percent, based on the weight of the composition. The aluminum particles are advantageously present as a multimodal, preferably bimodal distribution of spherical aluminum particles. The D₅₀ volume average particle size of the larger spherical aluminum particles is preferably in the range of from 5 μm, or from 7 μm, or from 8 μm, to 25 μm or to 10 μm; the D₉₉ volume average particle size of these larger particles is preferably <50 μm or <30 μm. The concentration of the larger spherical aluminum particles is preferably in the range of from 40 or from 45 or from 48 weight percent, to 60 or to 55 or to 52 weight percent, based on the weight of the composition.

The D₅₀ volume average particle size of the smaller spherical aluminum particles is preferably in the range of from 1 μm to 5 μm. The concentration of the smaller spherical aluminum particles is preferably in the range of from 15 or from 20 or from 23 weight percent, to 35 or to 30 or to 27 weight percent, based on the weight of the composition.

The D₅₀ volume average particle size of the zinc oxide (ZnO) particles and/or alumina particles is preferably in the range of from 50 nm or from 100 nm to 500 nm or to 200 nm or to 150 nm. The concentration of the ZnO particles and/or alumina particles is preferably in the range of from 10 or from 15 weight percent, to 25 or to 20 weight percent, based on the weight of the composition. D₅₀ and D₉₉ volume average particle sizes for aluminum, zinc oxide, and alumina particles refer to D₅₀ volume average particle diameter as measured using laser refractometry.

The boron nitride platelet particles have a thickness, as measured by Scanning Electron Microscopy (SEM), preferably in the range of from 750 nm to 5 μm, and a D₅₀ particle size diameter, as measured by dynamic light scattering, preferably in the range of from 3 μm to 40 μm. The diameter-thickness aspect ratio of the boron nitride platelet particles is preferably in the range of from 2:1 or from 3:1 or from 4:1, to 50:1 or to 30:1 or to 20:1 or to 10:1. The boron nitride platelet particles have a hexagonal crystal structure. During assembly the boron nitride platelet particles align approximately along the same direction as the substrates after the platelet particles are applied between the substrates. As such, the D₅₀ particle size of the boron nitride platelet particles does not influence the final bondline thickness. Commercially available examples of boron nitride platelet particles include CarboTherm PCTP30 Boron Nitride from St. Gobain and PolarTherm PT110 from Momentive Performance Materials. The concentration of boron nitride platelet particles is preferably in the range of from 0.5 or from 1 or from 2 weight percent to preferably 6 or to 5 or to 4 weight percent, based on the weight of the composition.

The C₁-C₂₀-alkyltri-C₁-C₆-alkoxysilane is preferably a C₆-C₁₆-alkyltrimethoxysilane or a C₈-C₁₂-alkyltrimethoxysilane. An example of a suitable C₁-C₂₀-alkyltri-C₁-C₆-alkoxysilane is n-decyltrimethoxysilane. The concentration of the C₁-C₂₀-alkyltri-C₁-C₆-alkoxysilane is preferably in the range of from 0.1 weight percent, to 2 or to 1 weight percent, based on the weight of the composition.

The concentration of the polydimethylsiloxane of structure 1 is preferably in the range of from 1 or from 3, to 8, based on the weight of the composition. R and R¹ are each preferably methyl; and x is preferably in the range of from 50 or from 80 or from 100, to preferably 180 or to 150 or to 130.

The composition may also comprise up to 10 weight percent of a carrier fluid, which is a polydimethylsiloxane or poly (phenylmethysiloxane-co-dimethylsiloxane) fluid having a viscosity in the range of from preferably 50 cSt or from 80 cSt to preferably 150 cSt or to 120 cSt. In one aspect, the non-curable thermal grease comprises from 1 or from 2 or from 4 weight percent, to 10 or to 8 or to 6 weight percent of the polydimethylsiloxane or poly (phenylmethysiloxane-co-dimethylsiloxane) carrier fluid, based on the weight of the composition.

The non-curable grease composition contains insufficient concentrations of crosslinking functional groups such as a combination of vinyl groups and Si—H groups to result in the curing of the grease. Preferably, the non-curable grease comprises neither vinyl groups nor Si—H groups.

The composition of the present invention provides excellent pump-out resistance along with desirable printability, viscosity, and thermal conductivity. Accordingly, in another aspect, the present invention is a microelectronic device comprising the non-curable thermal grease composition imbedded as a thermal interface material in the microelectronic device.

### EXAMPLES

In the following examples, all samples were mixed using a Flacktek mixer at 1500 rpm, unless otherwise noted; pbw refers to parts by weight.

Comparative Example 1—Preparation of a non-Curable Thermal Grease without Boron Nitride A phenylmethylsiloxane-dimethylsiloxane copolymer (100 cSt, 5.10 pbw, Product Code PMM-1021 from Gelest), structure 1 polydimethylsiloxane (each R and R¹═CH₃, x=110, Y=0, 1.99 pbw), n-decyltrimethoxysilane (0.17 pbw), and Zoco102 ZnO (~0.12 μm, 17.37 pbw) were added to a MAX100 cup and mixed for 15 s. TCP-2 Aluminum Powder (Toyo Aluminum K.K., particle size~2 μm, 25.12 pbw) was then added to the mixer and the components were mixed for 15 s. TCP-9 Aluminum Powder (Toyo Aluminum K. K., particle size~9 μm, 50.25 pbw) was then added to the mixer and the components were mixed for an additional 40 s. The components were hand-mixed using a spatula, then mixed in the mixer for 40 s. The formulation was then transferred to an aluminum pan and heated at 150° C. in vacuo for 1 h.

### Example 1—Preparation of a Non-Curable Thermal Grease with Boron Nitride

The steps used to prepare the non-curable thermal grease of Comparative Example 1 were repeated except that PCTP30 boron nitride (Saint Gobain, 3.0 pbw) was added to the mixer and the components mixed for 15 s after the addition and mixing of the TCP-9 Aluminum Powder (47.25 pbw). The components were hand-mixed using a spatula, then mixed in the mixer for 40 seconds. The formulation was then transferred to an aluminum pan and heated at 150° C. in vacuo for 1 h.

### Example 2—Preparation of a Non-Curable Thermal Grease with Boron Nitride

The steps used to prepare the non-curable thermal grease of Comparative Example 1 were repeated except that no phenylmethylsiloxane-dimethylsiloxane was added, the amount of structure 1 polydimethylsiloxane was 7.09 pbw, and PCTP30 boron nitride (Saint Gobain, 1.0 pbw) was added to the mixer and the components mixed for 15 s after the addition and mixing of the TCP-9 Aluminum Powder (49.25 pbw). The components were hand-mixed using a spatula, then mixed in the mixer for 40 seconds. The formulation was then transferred to an aluminum pan and heated at 150° C. in vacuo for 1 h.

Example 3—Preparation of a non-Curable Thermal Grease with Boron Nitride Structure 1 polydimethylsiloxane (each R and R′ ═CH₃, x=110, 354.5 g, 7.09 pbw), n-decyltrimethoxysilane (8.5 g, 0.17 pbw), and Zoco102 ZnO (~0.12 μm, 869 g, 17.37 pbw) were added to a 1-g Baker Perkins sigma blade mixer and the components mixed for 30 min. TCP-2 Aluminum Powder (1206 g, 25.12 pbw) then TCP-9 Aluminum Powder (2412 g, 47.25 pbw) were then added to the mixer and the components were mixed for an additional 55 min. BN (150 g, 3.00 pbw) was added to the mixer and the components were mixed for an additional 15 min. The mixture was dried in vacuo (25 Torr, 45 min) with mixing, then heated to 150° C. for 60 min, before heat was removed and the mixture was allowed to cool to room temperature.

### Example 4—Preparation of a Non-Curable Thermal Grease with Boron Nitride

The preparation as described in Example 2 was repeated except that 5.0 pbw boron nitride and 45.25 pbw TCP-9 were used.

### Viscosity Measurement

Complex viscosity at the dilatant point (Pa·s) was measured by ASTM D4440-15 (Standard Test Method for Plastics: Dynamic Mechanical Properties Melt Rheology) using instrument model ARES-G2 by TA Instruments equipped with 25-mm parallel plates (serrated steel). Testing conditions were based on strain sweep conducted at 25° C. with a gap of 2.0 mm. The measurements were taken using the standard procedure of 10 rad/oscillation frequency, sweeping from 0.01 to 200% strain amplitude with 20 sampling points per decade. The dilatant point was defined as the strain at which the complex viscosity starts increasing.

### Thermal Conductivity Measurement

Thermal conductivity was measured by ISO 22007-2: 2015 (Test Method for Determining Thermal Conductivity) using a C5501 sensor and Hot Disk Instrument TPS 2500 S from Hot Disk AB, Göteborg, Sweden. Grease material was filled into two cups with the planar sensor held between the cups. Analysis conditions: Fine-tuned analysis, Temperature drift compensation and time correction, calculation with selected between points 50-150.

### Printability Testing

Printability of the samples was measured using a 60-mesh metal screen to print a 25-cm×25-cm pattern with a thickness 200 μm. The screen was held above a heat sink 5 g of sample was applied on top of the screen. The sample was transferred through the screen onto the heat sink with a squeegee held at a 450 angle and applying a constant force and a constant drawing speed. Printability was considered good if the grease could be deposited on the heat sink.

### Pump-Out Resistance

A sample was applied by stencil onto the heat sink of an MSI GeForce RTX 2070 TRI FROZR Graphics card (die size: 24.0 mm×18.5=445 mm²). The graphics card was then assembled and installed into a computer. The following computer components were used for testing: CPU: AMD Ryzen 7 2700X 8-Core; Motherboard: ASUS TUF X470-PLIS GAMING; Memory: KINSTON DDR4 266 8 GB; Graphics Card: MSI GeForce RTX 2080 TRI FROZR (8 GB GDDR6, Nvidia Turing chip architecture); Solid State Drive: Intel SSD 760P Series (256 GB, M. 2 80-mm PCIe 3.0×4, 3D2, TLC); Monitor: Del U2417H; Keyboard: Dell; Mouse: Dell: PC Case: Antec P8 ATX; Power Supply: Antec NEO750W; KVM: MT-viki HK05.

The thermal cycling test was conducted by running the FurMark GPU stress test software developed by Geeks3D and is available at https://geeks3d.com/furmark/. A scrip (in AutoIt) included steps to turn on and off Furmark software and steps to change fan speed to control the temperature of the GPU card. Fan speed was controlled using MSI Afterburner available at Afterburner (msi.com).

The AutoIt script included the following steps: (1) The Furmark Program was opened; (2) the Furmark Stress Test Routine was activated; (3) the fan speed was adjusted to 30% of its maximum speed for 140,000 milliseconds for the heating cycle; (4) the Stress Test Routine was stopped; (5) the Furmark Program was turned off; (6) the fan speed was adjusted to 90% of its maximum speed for 180,000 milliseconds for the cool cycle; (7) the sequence was repeated. The procedure was used to cycle the temperature on the GPU card from 35° C. to 85° C. and back down to 35° C. After running 5000 cycles, the computer was shut down and the graphic card removed.

The graphics card was opened and the heat sink and die images were recorded. Areas were measured without sample material (bare spots) on the heat sink and the die arising from pump-out during the cycling test. The quantitative area of the bare spots was calculated using readily available software “sketchandclac”. The total bare spot area due to grease pump-out was divided by the total GPU die area (495 mm²) to determine % area of bare spots on the die. Results were classified as follows: EXCELLENT=less than 5% area of bare spot on the die; MODERATE=5-15% area of bare spot on the die; and BAD=greater than 15% area of bare spot on the die.

Table 3 is a summary of the thermal conductivity in W/m-K (TC), complex viscosity at the dilatant point in Pa·s (Viscosity), and pump-out resistance as measured by Bare Spot Area. Printability was found to be good for all samples.

TABLE 3
Summary of Properties for non-curable thermal grease

| | | | Bare Spot |
|---|---|---|---|
| Ex. No. | TC | Viscosity | Area |
| Comp. 1 | 5.0 | 104 | 23% |
| Ex. 1 | 5.9 | 92 | 4% |
| Ex. 2 | 5.6 | 128 | 12% |
| Ex. 3 | 6.1 | 145 | 5% |
| Ex. 4 | 6.8 | 167 | 11% |

The data demonstrate the striking positive impact of boron nitride on pump-out resistance. Surprisingly, improved pump-out resistance did not correlate with an increase in viscosity.

1. A non-curable thermal grease composition comprising, based on the weight of the composition, a) from 80 to 95 weight percent of one or more filler particles selected from the group consisting of aluminum, alumina, and zinc oxide; b) from 0.2 to 8 weight percent platelet boron nitride particles; and c) 0.2 to 10 weight percent of a trialkoxylated polydimethylsiloxane of structure 1: 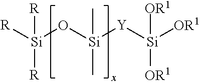
where R and R¹ are each independently C₁-C₆-alkyl, Y is O or CH₂—CH₂; and x is from 30 to 200;
wherein the non-curable thermal grease composition optionally comprises d) up to 10 weight percent of a polydimethylsiloxane or poly(phenylmethylsiloxane-dimethylsiloxane) carrier fluid having a viscosity in the range of from 30 to 200 cSt.

2. The composition of claim 1 which further comprises (e) from 0.05 to 1 weight percent of a C₁-C₂₀-alkyltri-C₁-C₆-alkoxysilane.

3. The composition of claim 1 which comprises, based on the weight of composition, from 85 to 95 weight percent aluminum and zinc oxide particles and/or alumina particles, wherein the aluminum particles are a bimodal distribution of larger and smaller spherical aluminum particles, wherein the D₅₀ volume average particle size of the larger spherical aluminum particles is in the range of from 5 μm to 15 μm, and wherein the D₉₉ volume average particle size of the larger spherical aluminum particles is <30 μm; wherein the D₅₀ volume average particle size of the smaller spherical aluminum particles is in the range of from 1 μm to 5 μm; wherein the D₅₀ volume average particle size of the zinc oxide particles and/or the alumina particles is in the range of from 50 nm to 200 nm.

4. The composition of claim 3 wherein, based on the weight of the composition, the concentration of the larger spherical aluminum particles is in the range of from 40 to 60 weight percent; the concentration of the smaller spherical aluminum particles is in the range of from 15 to 35 weight percent; and wherein the concentration of the zinc oxide particles and/or alumina particles is in the range of from 10 to 25 weight percent.

5. The composition of claim 1 wherein the concentration of the boron nitride platelet particles is in the range of from 0.5 to 6 weight percent, based on the weight of the composition, the D₅₀ particle size diameter of the boron nitride platelet particles is in the range of from 3 μm to 40 μm; and the thickness of the boron nitride platelet particles is in the range of from 750 nm to 5 μm.

6. The composition of claim 5 wherein the C₁-C₂₀-alkyltri-C₁-C₆-alkoxysilane is a C₆-C₁₆-alkyltrimethoxysilane, and wherein the concentration of the C₆-C₁₆-alkyltrimethoxysilane is in the range of from 0.1 to 2 weight percent, based on the weight of the composition; wherein the boron nitride platelet particles have a diameter:thickness aspect ratio in the range of from 3:1 to 30:1.

7. The composition of claim 6 wherein the C₆-C₁₆-alkyltrimethoxysilane is a C₈-C₁₂-alkyltrimethoxysilane; wherein the polydimethylsiloxane of structure 1 is represented by the following structure: 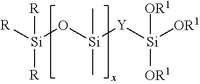
where each R and R¹ is methyl, x is from 50 to 180, and Y is O; wherein the concentration of the polydimethylsiloxane of structure 1 is in the range of from 1 to 10 weight percent, based on the weight of the composition; wherein the boron nitride platelet particles have a diameter:thickness aspect ratio in the range of from 3:1 to 20:1.

8. The composition of claim 7 which comprises from 1 to 10 weight percent of a polydimethylsiloxane or poly(phenylmethysiloxane-co-dimethylsiloxane) carrier fluid, based on the weight of the non-curable thermal grease; wherein the viscosity of the carrier fluid is in the range of from 30 cSt to 150 cSt.

9. The composition of claim 8 wherein the concentration of the boron nitride platelet particles is in the range of from 1 to 5 weight percent, based on the weight of the composition.

10. The composition of claim 7 wherein the concentration of the boron nitride platelet particles is in the range of from 2 to 4 weight percent, based on the weight of the composition; wherein the C₈-C₁₂-alkyltrimethoxysilane is n-decytrimethoxysilane; wherein x is from 80 to 130; wherein the boron nitride platelet particles have a diameter:thickness aspect ratio in the range of from 4:1 to 10:1.

10. The composition of claim 7 which comprises, based on the weight of the non-curable composition, from 90 to 95 weight percent aluminum and zinc oxide particles, wherein the D₅₀ volume average particle size of the larger spherical aluminum particles is in the range of from 7 μm to 25 μm; and the D₅₀ volume average particle size of the zinc oxide particles is in the range of from 100 nm to 200 nm;
wherein, based on the weight of the composition, the concentration of the larger spherical aluminum particles is in the range of from 45 to 55 weight percent; the concentration of the smaller spherical aluminum particles is in the range of from 20 to 30 weight percent; and the concentration of the zinc oxide particles is in the range of from 15 to 20 weight percent.

11. The composition of claim 8 which comprises from 2 to 8 weight percent of the polydimethylsiloxane or phenylmethysiloxane-co-dimethylsiloxane carrier fluid, based on the weight of the composition; wherein the viscosity of the carrier fluid is in the range of from 30 cSt to 120 cSt.

12. A microelectronic device comprising the non-curable thermal grease composition of claim 1 imbedded as a thermal interface material in the microelectronic device.
